(19) United States
(12) Patent Application Publication
(10) Pub. No.: US 2024/0241158 A1
(43) Pub. Date: Jul. 18, 2024

(54) SELF-PRODUCED ENERGY SURPLUS/SHORTAGE INFORMATION GENERATION DEVICE, SELF-PRODUCED ENERGY SURPLUS/SHORTAGE INFORMATION GENERATION METHOD, PHOTOVOLTAIC SYSTEM, MICROGRID ENERGY SUPPLY AND DEMAND SYSTEM, AND MICROGRID ENERGY SUPPLY AND DEMAND METHOD

(71) Applicant: Takahiro TANAKA, Niiza-shi, Saitama (JP)

(72) Inventors: Takahiro TANAKA, Niiza-shi, Saitama (JP); John BORLAND, Aiea, HI (US)

(21) Appl. No.: 18/289,686

(22) PCT Filed: Aug. 22, 2022
(86) PCT No.: PCT/JP2022/031497

§ 371 Date: Nov. 6, 2023

(30) Foreign Application Priority Data
Dec. 23, 2021 (WO) PCT/JP2021/048064
Jun. 4, 2022 (WO) PCT/JP2022/022696

(51) Int. Cl. G01R 21/133; H02J 13/00

(52) U.S. Cl. CPC G01R 21/133; H02J 13/00002

(57) ABSTRACT

Provided are a self-produced energy surplus/shortage information generation device, a self-produced energy surplus/shortage information generation method, a photovoltaic system, a microgrid energy supply and demand system, and a microgrid energy supply and demand method that take the use state of renewable energy in an energy receiving unit into consideration. In a device that generates information related to surplus or shortage of self-produced energy in an energy receiving unit 2 in which electric power supplied from a commercial grid 20 and a renewable energy power generation device 30 is consumed by a load, self-produced energy surplus/shortage information related to surplus or shortage of self-produced energy in the energy receiving unit 2 is generated based on a measured power generation amount of the renewable energy power generation device 30 and a preset setting power generation amount when a daytime/nighttime discrimination unit determines that it is daytime.

### TECHNICAL FIELD

The present invention relates to a self-produced energy surplus/shortage information generation device, a self-produced energy surplus/shortage information generation method, a photovoltaic system, a microgrid energy supply and demand system, and a microgrid energy supply and demand method.

### BACKGROUND ART

An energy supply system is known that includes a plurality of energy receiving units having energy supply sources and demand facilities that demand energy supplied from the energy supply sources, and management means that manages the plurality of energy receiving units (see PTL 1). In the energy supply system of PTL 1, when the storage amount of an energy storage device that stores surplus power in the energy receiving unit is below a threshold, it is determined that external energy supply is required, and energy is supplied to the energy receiving unit.

### CITATION LIST

### Patent Literature

PTL 1: JP2021-158731A

### SUMMARY OF INVENTION

### Technical Problem

However, in the energy supply system described in PTL 1, the use state of renewable energy in the energy receiving unit is not taken into consideration, and there is a risk that renewable energy will not be effectively utilized.

The present invention has been made in view of the above-mentioned circumstances, and an object thereof is to provide a self-produced energy surplus/shortage information generation device, a self-produced energy surplus/shortage information generation method, a photovoltaic system, a microgrid energy supply and demand system, and a microgrid energy supply and demand method that take the use state of renewable energy in an energy receiving unit into consideration.

### Solution to Problem

In order to achieve the above object, the present invention provides
a self-produced energy surplus/shortage information generation device that generates information related to surplus or shortage of self-produced energy in an energy receiving unit in which electric power supplied from a commercial grid and a photovoltaic device is consumed by a load, the device including:
a daytime/nighttime discrimination unit that discriminates between daytime and nighttime; and
a surplus/shortage information generation unit that generates self-produced energy surplus/shortage information related to surplus or shortage of self-produced energy in the energy receiving unit based on a measured power generation amount of the photovoltaic device and a preset setting power generation amount when the daytime/nighttime discrimination unit determines that it is daytime.

In the self-produced energy surplus/shortage information generation device,
the self-produced energy surplus/shortage information may be classified depending on at least whether the self-produced energy in the energy receiving unit is in a surplus state and whether the self-produced energy in the energy receiving unit is in a shortage state.

The self-produced energy surplus/shortage information generation device may further include
a measured degree calculation unit that calculates a degree of the measured power generation amount with respect to the setting power generation amount based on the measured power generation amount and the setting power generation amount as a measured power generation degree, and
the surplus/shortage information generation unit may generate the self-produced energy surplus/shortage information based on measured degree comparison information obtained by comparing the measured power generation degree with a preset setting power generation degree when the daytime/nighttime discrimination unit determines that it is daytime.

The self-produced energy surplus/shortage information generation device may further include
a use degree calculation unit that calculates a use degree of electric power supplied from the photovoltaic device in entire supply power based on grid power information related to electric power supplied from the commercial grid and self-produced energy power information related to electric power supplied from the photovoltaic device as a self-produced energy use degree, and
the surplus/shortage information generation unit may generate the self-produced energy surplus/shortage information based on the measured power generation amount, the setting power generation amount, and use degree comparison information obtained by comparing the self-produced energy use degree and a preset setting use degree.

In the self-produced energy surplus/shortage information generation device,
electric power may be supplied to the load from a storage battery in addition to the commercial grid and the photovoltaic device,
the self-produced energy power information may relate to electric power supplied from the photovoltaic device and the storage battery, and
the use degree calculation unit may calculate a use degree of the electric power supplied from the photovoltaic device and the storage battery in the entire supplied electric power as the self-produced energy use degree.

The self-produced energy surplus/shortage information generation device may further include
an availability determination unit that determines whether the storage battery is in an available state or a non-available state, and
the surplus/shortage information generation unit may generate the self-produced energy surplus/shortage information based on the measured power generation amount and the setting power generation amount, the use degree comparison information, and whether the storage battery is in the available state or the non-available state when the daytime/nighttime discrimination unit determines that it is daytime.

In the self-produced energy surplus/shortage information generation device,
the availability determination unit may determine whether the storage battery is in the available state or the non-available state based on the time of day and a remaining capacity of the storage battery when the daytime/nighttime discrimination unit determines that it is night, and
the surplus/shortage information generation unit may generate the self-produced energy surplus/shortage information based on the use degree comparison information and whether the storage battery is in the available state or the non-available state when the daytime/nighttime discrimination unit determines that it is nighttime.

The self-produced energy surplus/shortage information generation device may further include
a reverse power flow detection unit that detects a reverse power flow in which electric power is supplied from the photovoltaic device to the commercial grid, and
the surplus/shortage information generation unit may generate the self-produced energy surplus/shortage information based on the measured power generation amount, the setting power generation amount, the use degree comparison information, whether the storage battery is in the available state or the non-available state, and whether the reverse power flow is detected by the reverse power flow detection unit when the daytime/nighttime discrimination unit determines that it is daytime.

Moreover, the present invention provides
a self-produced energy surplus/shortage information generation method for generating information related to surplus or shortage of self-produced energy in an energy receiving unit in which electric power supplied from a commercial grid and a photovoltaic device is consumed by a load, the method including:
discriminating between daytime and nighttime;
generating self-produced energy surplus/shortage information related to surplus or shortage of self-produced energy in the energy receiving unit based on a measured power generation amount of the photovoltaic device and a preset setting power generation amount when it is determined that it is daytime.

Moreover, the present invention provides
an energy supply and demand system of a microgrid to which a plurality of energy receiving units connected to each other by a power grid belongs, the system including:
the self-produced energy surplus/shortage information generation device, and
the surplus/shortage information generation device generates the self-produced energy surplus/shortage information of each energy receiving unit belonging to the microgrid, the system further including:
a supply and demand adjustment unit that supplies electric power from the energy receiving unit classified into the surplus state by the surplus/shortage information generation device to the energy receiving unit classified into the shortage state.

Moreover, the present invention provides
a photovoltaic system including: an energy receiving unit in which electric power supplied from a commercial grid and a photovoltaic device is consumed by a load; and
the self-produced energy surplus/shortage information generation device,
the load includes a heat storage device that stores heat in a predetermined heat storage unit, the system further including:
a heat storage control unit that increases a heat storage action of the heat storage device when the self-produced energy is classified into the surplus state by the surplus/shortage information generation device.

In the photovoltaic system,
the heat storage device may include an air-conditioner that cools and heats a predetermined room, the system further including:
an air-conditioning restriction unit that restricts increase or decrease of the heat storage action of the air-conditioner by the heat storage control unit based on room information of the predetermined room.

The photovoltaic system may further include
a restriction control unit that controls whether restriction of increase or decrease of the heat storage action by the air-conditioning restriction unit will be enabled or disabled based on an input from an air-conditioning operation unit that inputs operations on the air-conditioner.

Moreover, the present invention provides
an energy supply and demand system of a microgrid to which a plurality of energy receiving units connected to each other by a power grid belongs,
the energy receiving units are classified depending on at least whether the self-produced energy in the energy receiving unit is in a surplus state and whether the self-produced energy in the energy receiving unit is in a shortage state, and
electric power is supplied from the energy receiving unit classified into the surplus state to the energy receiving unit classified into the shortage state.

Moreover, the present invention provides
an energy supply and demand method of a microgrid to which a plurality of energy receiving units connected to each other by a power grid belong, the method including:
classifying the energy receiving units depending on at least whether the self-produced energy in the energy receiving unit is in a surplus state and whether the self-produced energy in the energy receiving unit is in a shortage state; and
supplying electric power the energy receiving unit classified into the surplus state to the energy receiving unit classified into the shortage state.

### Effect of the Invention

According to this invention, the renewable energy can be utilized effectively in consideration of the use state of the renewable energy in an energy receiving unit.

### BRIEF DESCRIPTION OF DRAWINGS

FIG. 1 is a configuration block diagram of a photovoltaic system showing a first embodiment of the present invention.

FIG. 2 is a control block diagram of the photovoltaic system.

FIG. 3 is a flowchart showing the operation of the photovoltaic system.

FIG. 4 is a flowchart showing an operation in a heat storage increasing mode.

FIG. 5 is a flowchart showing operation in a heat storage decreasing mode.

FIG. 6 is a flowchart showing the operation of the photovoltaic system.

FIG. 7 is a configuration block diagram of a photovoltaic system showing a second embodiment of the present invention.

FIG. 8 is a control block diagram of the photovoltaic system.

FIG. 9 is a flowchart showing the operation of the photovoltaic system.

FIG. 10 is a flowchart showing the operation of the photovoltaic system.

FIG. 11 is a flowchart showing the operation of the photovoltaic system.

FIG. 12 is a control block diagram of a photovoltaic system showing a modified example.

FIG. 13 is a flowchart showing the operation of a photovoltaic system showing a modified example.

FIG. 14 is an energy block diagram of a single-microgrid energy supply and demand system showing a third embodiment of the present invention.

FIG. 15 is a communication block diagram of a single-microgrid energy supply and demand system.

FIG. 16 is a block diagram related to energy of a multiple-microgrid energy supply and demand system showing a fourth embodiment of the present invention.

FIG. 17 is a block diagram of communication in a multiple-microgrid energy supply and demand system.

FIG. 18 is a block diagram related to communication in a multiple-microgrid energy supply and demand system showing a modified example.

FIG. 19 is a graph showing hourly power supply and power consumption amounts in the photovoltaic system of the Example.

FIG. 20 is a graph showing hourly power supply and power consumption amounts in the photovoltaic system of a first comparative example.

FIG. 21 is a graph showing hourly power supply and power consumption amounts in the photovoltaic system of the first comparative example.

### DESCRIPTION OF EMBODIMENTS

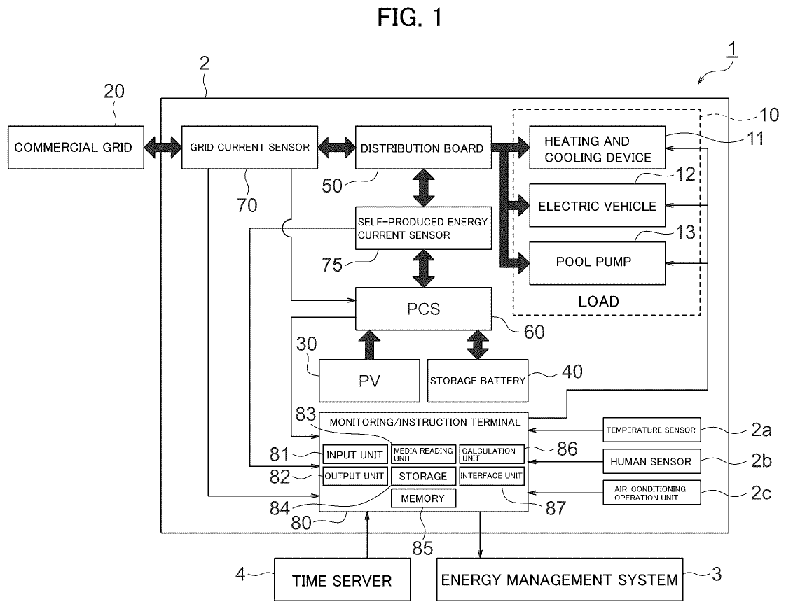

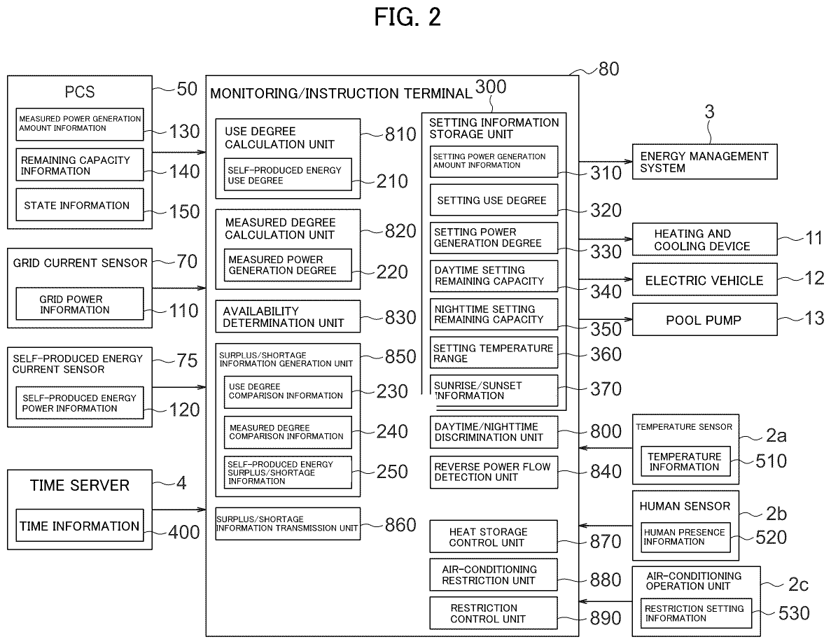

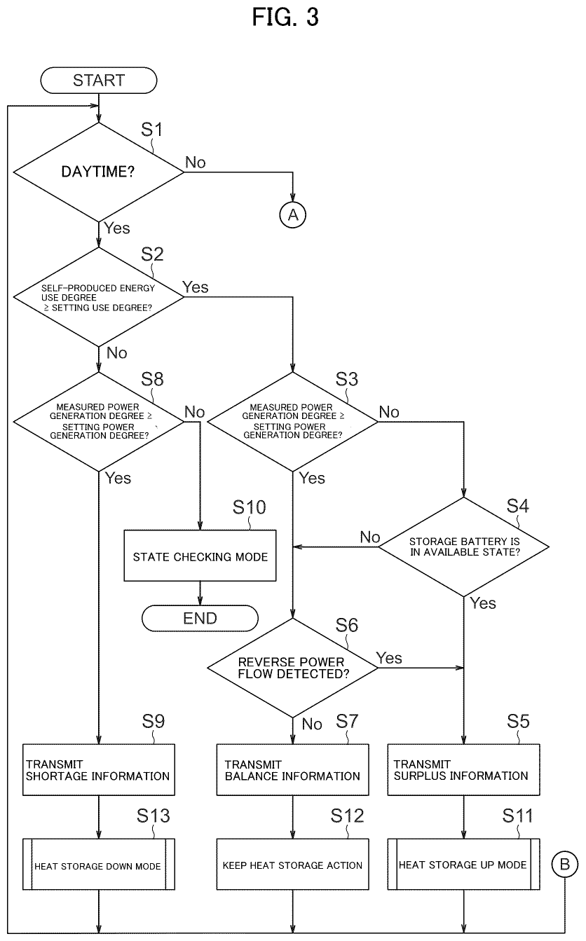

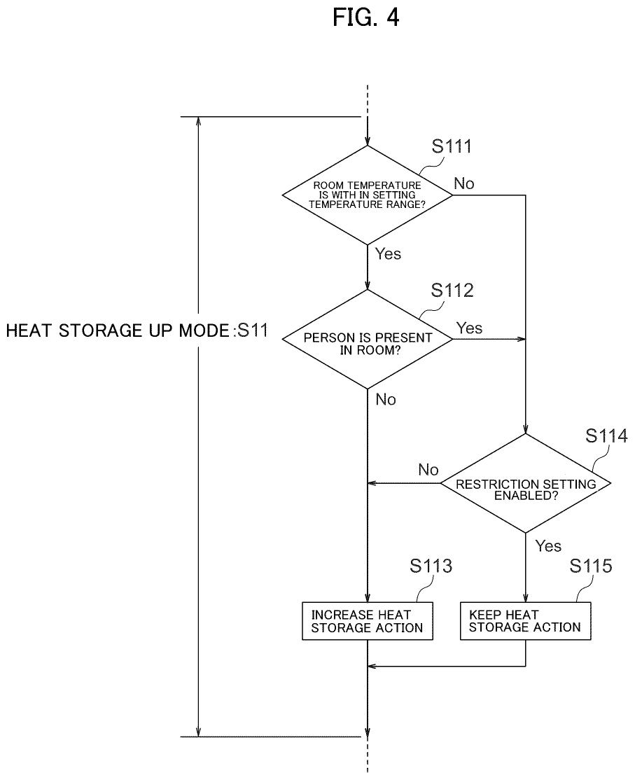

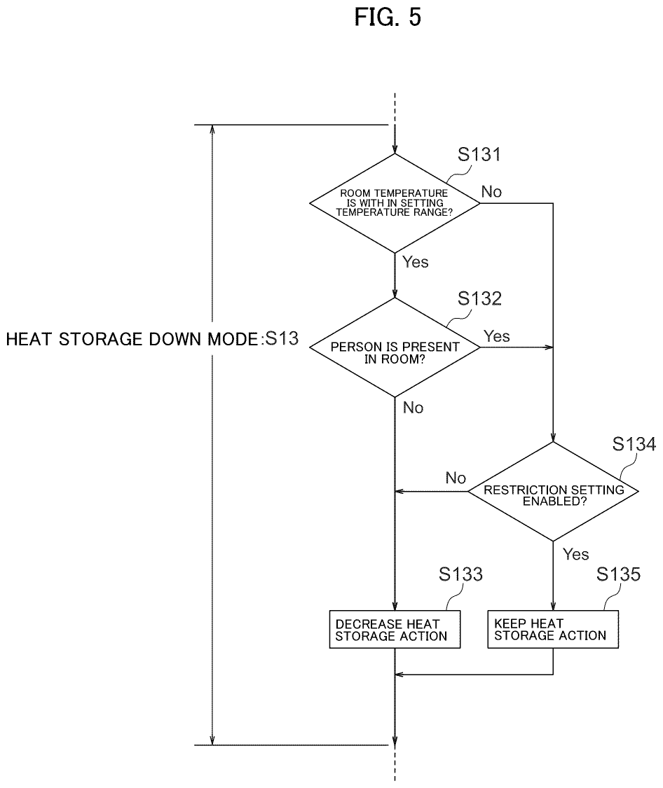

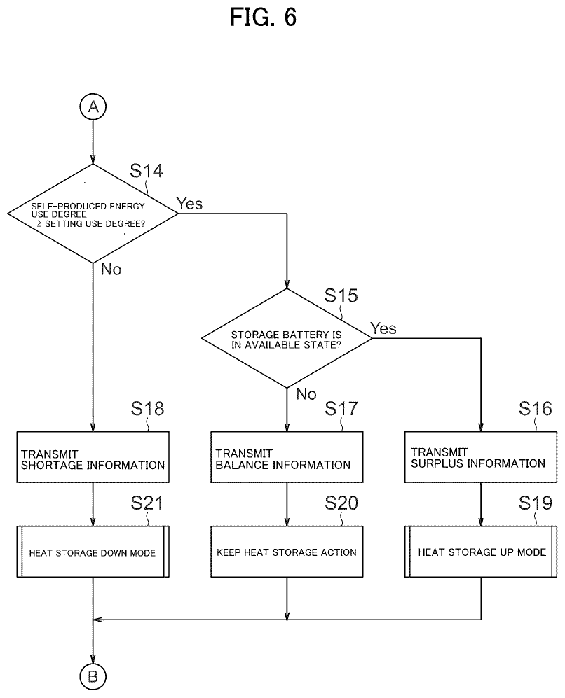

FIGS. 1 to 6 show a first embodiment of the present invention, in which FIG. 1 is a configuration block diagram of a photovoltaic system, FIG. 2 is a control block diagram of the photovoltaic system, FIGS. 3 and 6 are flowcharts showing the operation of the photovoltaic system, FIG. 4 is a flowchart showing the operation in the heat storage increasing mode, and FIG. 5 is a flowchart showing the operation in the heat storage decreasing mode.

As shown in FIG. 1, this photovoltaic system 1 is applied to an energy receiving unit 2 in which electric power is supplied to a load 10 from a commercial grid 20 side and a photovoltaic device (PV) 30 side. In the present embodiment, the load 10 includes a heating and cooling device 11, an electric vehicle 12 and a pool pump 13 of a residential swimming pool. This energy receiving unit 2 is monitored by an energy management system (EMS) 3 together with other energy receiving units not shown in FIG. 1. The energy management system 3 receives electric power from the energy receiving units in an energy surplus state among the energy receiving units to be monitored, and supplies electric power to the energy receiving units in an energy shortage state.

In the present embodiment, the energy receiving unit 2 is a house. Note that the energy receiving unit 2 may be, for example, a facility. The heating and cooling device 10 stores heat in a predetermined heat storage unit. In the present embodiment, the heating and cooling device 10 includes an air-conditioner that cools and heats a predetermined room, and a water heater that can store water heated by an electric heater. Note that FIG. 1 does not show the load 10 other than the heating and cooling device 11, the electric vehicle 12, and the pool pump 13. Electric power from the commercial grid 20, the photovoltaic device 30 and the storage battery 40 is supplied to the load 10 via a distribution board 50. Note that, instead of the distribution board 50, another facility having a connection function, such as a connection box, can be used. In the present embodiment, a reverse power flow occurs in which electric power is supplied from the photovoltaic device 30 to the commercial grid 20. That is, in the present embodiment, electric power is purchased from the commercial grid 20 and sold to the commercial grid 20.

The photovoltaic device 30 has a panel that converts light energy into electrical energy, and the energy receiving unit 2 is provided with a power conditioner (PCS) 60 that converts this electrical energy from direct current to alternating current. The power conditioner 60 manages the storage battery 40 that charges the electric power generated by the photovoltaic device 30. The electric power stored in the storage battery 40 is discharged and supplied to the load as necessary. In addition, in the present embodiment, the storage battery 40 can also be charged with the electric power from the commercial grid 20.

In the present embodiment, a grid current sensor 70 that detects a current flowing in and out between the commercial grid 20 and the distribution board 50 and a self-produced energy current sensor 75 that detects a current flowing in and out between the power conditioner 60 and the distribution board 50 are provided. As shown in FIG. 2, the current value detected by the grid current sensor 70 is transmitted to a monitoring/instruction terminal 80 as grid power information 110 related to the electric power supplied from the commercial grid 20. In addition, the current value detected by the self-produced energy current sensor 75 is transmitted to the monitoring/instruction terminal 80 as self-produced energy power information 120 related to the electric power supplied from the photovoltaic device 30 and the storage battery 40.

Further, the energy receiving unit 2 is provided with a temperature sensor 2a that detects the temperature in the room that is cooled and heated by the air-conditioner, and a human sensor 2b that detects the presence of a person in the room. As shown in FIG. 2, the room temperature detected by the temperature sensor 2a is transmitted to the monitoring/instruction terminal 80 as temperature information 510. Information related to the presence of a person detected by the human sensor 2b is transmitted to the monitoring/instruction terminal 80 as human presence information 520. The air-conditioner is operated through an air-conditioning operation unit 2c that inputs operations on the air-conditioner. In the present embodiment, the air-conditioning operation unit 2c is a remote controller detachably installed on the wall surface of the room. With the air-conditioning operation unit 2c, a person in the room can perform various settings of the air-conditioner such as turning on/off of the air-conditioner, switching operation modes such as heating, dehumidification, and cooling, adjustment of the air volume, or changing of the setting temperature of the room. In the present embodiment, the air-conditioning operation unit 2c accepts a setting as to whether to enable or disable the restriction of increase or decrease of the heat storage action, which will be described later. Specifically, either the “manual mode” or the “automatic mode” can be alternatively selected by the air-conditioning operation unit 2c. The restriction of increase or decrease of the heat storage action is enabled when the “manual mode” is selected, and the restriction of increase or decrease of the heat storage action is disabled when the “automatic mode” is selected. As shown in FIG. 2, the setting related to the restriction received by the air-conditioning operation unit 2c is transmitted to the monitoring/instruction terminal 80 as restriction setting information 530.

The monitoring/instruction terminal 80 monitors various pieces of information in the energy receiving unit 2 and issues instructions related to control and the like to various devices based on the various pieces of information. In the present embodiment, the monitoring/instruction terminal 80 serves as a self-produced energy surplus/shortage information generation device. The monitoring/instruction terminal 80 can be, for example, a terminal installed inside a house, or can be a portable terminal outside the house.

The monitoring/instruction terminal 80 is configured of a computer such as a personal computer or a workstation, and includes an input unit 81, an output unit 82, a media reading unit 83, a storage 84, a memory 85, a calculation unit 86, and an interface unit 87, which are interconnected by a system bus. The input unit 81 has a keyboard, a mouse, and the like, which are operated by the terminal user, and inputs various operation signals related to program execution and the like from the terminal user. The output unit 82 has a display for displaying data and the like, and can display the execution progress, results, and the like of various programs. The input unit 81 and the output unit 82 may be integrated input/output means such as a touch panel. In this case, input can be performed by touching a predetermined position with the user's finger or a pen-type input device. The media reading unit 83 is configured of, for example, a CD drive, a DVD drive, a USB connector, and the like. The storage 84 is a hard disk, a SSD, or the like, and stores various programs, various pieces of electronic data, and the like. The stored programs, data, and the like can be input and output as needed. The memory 85 is a ROM, a RAM, or the like, and stores an execution program or the like read from the storage 84 by the calculation unit 86. The calculation unit 86 is a CPU or the like and can realize various processes such as generation of self-produced energy surplus/shortage information 250 and control of the heating and cooling device 10, which will be described later by controlling the processing of the entire computer, such as various calculations and data input/output with each hardware component, based on a control program such as an OS and a program related to self-produced energy stored in the memory 85.

As shown in FIG. 2, the monitoring/instruction terminal 80 acquires the pieces of power information 110 and 120 from the current sensors 70 and 75, and acquires the measured power generation amount information 130 of the photovoltaic device 30, the remaining capacity information 140 and the state information 150 of the storage battery 40 from the power conditioner 60. The state information 150 is information indicating whether the storage battery 40 is in a charging state, a discharging state, or a standby state. The monitoring/instruction terminal 80 also acquires the time information 400 from the time server 4. Further, the monitoring/instruction terminal 80 acquires temperature information 510 and human presence information 520 from the temperature sensor 2a and the human sensor 2b. The monitoring/instruction terminal 80 has a setting information storage unit 300 that stores various pieces of setting information. In the present embodiment, the setting information storage unit 300 stores the setting power generation amount information 310, the setting use degree 320, the setting power generation degree 330, the daytime setting remaining capacity 340, the nighttime setting remaining capacity 350, the setting temperature range 360, and the sunrise/sunset information 370. The setting information stored in the setting information storage unit 300 can be rewritten by input or the like from the user, the outside, and the like.

The monitoring/instruction terminal 80 has a daytime/nighttime discrimination unit 800 that discriminates between daytime and nighttime. In the present embodiment, the daytime/nighttime discrimination unit 800 discriminates between daytime and nighttime by comparing the time information 400 acquired from the time server 4 with the sunrise and sunset times of the sunrise/sunset information 370 stored in advance. The daytime/nighttime determination method of the daytime/nighttime discrimination unit 800 is arbitrary. For example, it can also be determined based on the intensity of sunlight detected by an illuminance sensor, the outside temperature detected by a thermometer, the power generation amount of the photovoltaic device 30 according to the time of day, and the like. Moreover, the daytime and nighttime can be discriminated according to the user's input that it is daytime or nighttime.

The monitoring/instruction terminal 80 has a use degree calculation unit 810 that calculates the degree of use of the electric power supplied from the photovoltaic device 30 and the storage battery 40 in the entire supply power as the self-produced energy use degree 210 based on the grid power information 110 and the self-produced energy power information 120. In the present embodiment, the self-produced energy use degree 210 is calculated by dividing the current value detected by the self-produced energy current sensor 75 by the sum of the current values detected by the grid current sensor 70 and the self-produced energy current sensor 75. Here, separately from the distribution board 50 to which electric power is supplied from the commercial grid 20, the photovoltaic device 30, and the storage battery 40, another distribution board to which electric power is supplied only from the photovoltaic device 30 and the storage battery 40 may be provided, for example, for the purpose of supplying electric power preferentially to important loads in the event of a disaster. In this case, separately from the self-produced energy current sensor 75, a second self-produced energy current sensor may be provided between the photovoltaic device 30 and the storage battery 40 and the other distribution board, and the self-produced energy power information 120 may be obtained by summing the current values detected by the self-produced energy current sensor 75 and the second self-produced energy current sensor. The self-produced energy use degree 210 may be calculated using, for example, the difference between the current values detected by the grid current sensor 70 and the self-produced energy current sensor 75, and the method of calculating the self-produced energy use degree 210 can be changed as appropriate.

The monitoring/instruction terminal 80 has a measured degree calculation unit 820 that calculates the degree of the measured power generation amount of the photovoltaic device 30 with respect to the setting power generation amount as the measured power generation degree 220 based on the measured power generation amount information 130 and the setting power generation amount information 310. In the present embodiment, the measured power generation degree 220 is calculated by dividing the measured power generation amount by the setting power generation amount. Note that the measured power generation degree 220 may be calculated using, for example, the difference between the measured power generation amount and the setting power generation amount, and the method of calculating the measured power generation degree 220 can be changed as appropriate. In the present embodiment, the setting power generation amount information 310 includes information related to the predicted power generation amount, and can be set from, for example, weather forecast, correlation between a solar radiation amount and a power generation amount, the use amount of general model houses and facilities, the actual value of the power generation amount of each energy receiving unit 2, and the like. When the setting power generation amount information is set from the actual value of the power generation amount of each energy receiving unit 2, for example, the setting power generation amount may be determined from the actual value obtained the previous day, or the setting power generation amount may be updated by continuously acquiring and learning the actual value. In addition, the setting power generation amount information 310 can be set for each region or season, set based on the family structure of the people who live there, or can be set separately for weekdays and holidays.

The monitoring/instruction terminal 80 has an availability determination unit 830 that determines whether the storage battery 40 is in an available state or a non-available state. In the present embodiment, when the daytime/nighttime discrimination unit 800 determines that it is daytime, the availability determination unit 830 determines whether the storage battery 40 is in an available state or a non-available state based on the remaining capacity information 140 and the state information 150 of the storage battery 40. Specifically, as for the remaining capacity of the storage battery 40, when the daytime/nighttime discrimination unit 800 determines that it is daytime, the availability determination unit 830 compares the remaining capacity of the storage battery 40 with a preset daytime setting remaining capacity 340. Further, in the present embodiment, when the daytime/nighttime discrimination unit 800 determines that it is nighttime, the availability determination unit 830 determines whether the storage battery 40 is in an available state or a non-available state based on the remaining capacity information 140 and the time information 400 of the storage battery 40. Specifically, when the daytime/nighttime discrimination unit 800 determines that it is nighttime, the availability determination unit 830 compares the remaining capacity of the storage battery 40 with the preset nighttime setting remaining capacity 350. In the present embodiment, the nighttime setting remaining capacity 350 changes according to the time of day, and has a maximum value immediately after daytime switches to nighttime, and a minimum value immediately before nighttime switches to daytime. The availability determination unit 830 refers to the nighttime setting remaining capacity 350 at the time of day from the time information 400 and compares the remaining capacity of the storage battery 40 with the referred nighttime setting remaining capacity 350.

The monitoring/instruction terminal 80 has a reverse power flow detection unit 840 that detects a reverse power flow in which electric power is supplied from the photovoltaic device 30 to the commercial grid 20. In the present embodiment, the reverse power flow is detected by the current value of the grid current sensor 70.

The monitoring/instruction terminal 80 has a surplus/shortage information generation unit 850 that generates self-produced energy surplus/shortage information 250 related to surplus or shortage of self-produced energy in the energy receiving unit 2 based on use degree comparison information 230 obtained by comparing the self-produced energy use degree 210 with preset setting use degree 320, measured degree comparison information 240 obtained by comparing the measured power generation degree 220 with a preset setting power generation degree 330, whether the storage battery 40 is in an available state or a non-available state, and whether a reverse power flow is detected by the reverse power flow detection unit 840 when the daytime/nighttime discrimination unit 800 determines that it is daytime. In the present embodiment, the use degree comparison information 230 is information related to the magnitude relationship between the self-produced energy use degree 210 and the setting use degree 320, and the measured degree comparison information 240 is information related to the magnitude relationship between the measured power generation degree 220 and the setting power generation degree 330. Further, when the daytime/nighttime discrimination unit 800 determines that it is nighttime, the surplus/shortage information generation unit 850 generates the self-produced energy surplus/shortage information 250 based on the use degree comparison information 230 and whether the storage battery 40 is in an available state or a non-available state. The surplus/shortage information generation unit 850 classifies the surplus or shortage of self-produced energy in the energy receiving unit 2 into one of a surplus state, a balanced state, and a shortage state, and uses this as the self-produced energy surplus/shortage information 250.

The monitoring/instruction terminal 80 has a surplus/shortage information transmission unit 860 that transmits the self-produced energy surplus/shortage information 250 to a predetermined device. The surplus/shortage information transmission unit 860 transmits the self-produced energy surplus/shortage information 250 to an integrated energy sharing system 3. The energy management system 3 receives energy from each energy receiving unit 2 or supplies energy to each energy receiving unit 2 based on the received self-produced energy surplus/shortage information 250.

The monitoring/instruction terminal 80 has a heat storage control unit 870 that increases the heat storage action of the heating and cooling device 10 as a heat storage device based on the self-produced energy surplus/shortage information 250 related to the power of the energy receiving unit 2. Specifically, the heat storage control unit 870 increases the heat storage action of the heating and cooling device 10 when the self-produced energy is in a surplus state, maintains the heat storage action of the heating and cooling device 10 when the self-produced energy is in a balanced state, and decreases the heat storage action of the heating and cooling device 10 when the self-produced energy is in a shortage state. In the present embodiment, for example, when the self-produced energy is in a surplus state, the heating action or cooling action of the air-conditioner is increased to increase the amount of heat stored in the room, and the heating action of the water heater is increased to increase the amount of heat stored in the stored water.

The monitoring/instruction terminal 80 also has an air-conditioning restriction unit 880 that restricts increase or decrease of the heat storage action of the air-conditioner by the heat storage control unit 870 based on room information of a predetermined room that is cooled and heated by the air-conditioner. In the present embodiment, the room information is the temperature information 510 and the human presence information 520. Specifically, it is determined whether the room temperature is within a preset setting temperature range 360, and if not, the increase or decrease of the heat storage action is prohibited. In the present embodiment, the air-conditioning control unit 870 prohibits increase or decrease of the heat storage action even when there is a person in the room. Furthermore, the monitoring/instruction terminal 80 has a restriction control unit 890 that controls whether the restriction of increase or decrease of the heat storage action by the air-conditioning restriction unit 880 will be enabled or disabled based on the input from the air-conditioning operation unit 2c.

The operation of the photovoltaic system 1 configured as described above will be described with reference to the flowcharts of FIGS. 3 to 6.

As shown in FIG. 3, the monitoring/instruction terminal 80 determines whether it is daytime or nighttime based on the time information 400 and the sunrise/sunset information 370 (step S1). If it is determined that it is daytime in step S1, the self-produced energy use degree 210 and the setting use degree 320 are compared and it is determined whether the self-produced energy use degree 210 is equal to or greater than the setting use degree 320 (step S2). The setting use degree 320 can be set arbitrarily, and is set to 80% in the present embodiment. In step S2, cases are classified depending on whether the self-produced energy use degree 210 is equal to or greater than the setting use degree 320. However, it is not important how the case where the self-produced energy use degree 210 and the setting use degree 320 are equal will be classified. In short, it is sufficient to classify cases into a case where the self-produced energy use degree 210 is greater than the setting use degree 320 and a case where the self-produced energy use degree 210 is less than the setting use degree 320.

In step S2, if the setting use degree 320 is equal to or greater than the self-produced energy use degree 210, the measured power generation degree 220 and the setting power generation degree 330 are compared and it is determined whether the measured power generation degree 220 is equal to or greater than the setting power generation degree 330 (step S3). The setting power generation degree 330 can be set arbitrarily, and is set to 80% in the present embodiment. In step S3, cases are classified depending on whether the measured power generation degree 220 is equal to or greater than the setting power generation degree 330. However, it is not important how the case where the measured power generation degree 220 and the setting power generation degree 330 are equal will be classified. In short, it is sufficient to classify cases into a case where the measured power generation degree 220 is greater than the setting power generation degree 330 and a case where the measured power generation degree 220 is less than the setting power generation degree 330.

If the measured power generation degree 220 is less than the setting power generation degree 330 in step S3, it is determined whether the storage battery 40 is in an available state (step S4). In the daytime, when the storage battery 40 is in a charging state or a standby state and the battery remaining capacity is equal to or greater than the daytime setting remaining capacity 340, it is determined that the battery is in an available state. The daytime setting remaining capacity 340 can be set arbitrarily, and is set to 80% in the present embodiment. In step S4, cases are classified depending on whether the remaining battery capacity is equal to or greater than the daytime setting remaining capacity 340. However, it is not important how the case where the remaining battery capacity and the daytime setting remaining capacity 340 are equal will be classified. In short, it is sufficient to classify case into a case where the remaining battery capacity is greater than the daytime setting remaining capacity 340 and a case where the remaining battery capacity is less than the daytime setting remaining capacity 340.

When the storage battery 40 is in an available state in step S4, it is determined that the surplus or shortage of the self-produced energy in the energy receiving unit 2 is in a surplus state, and the self-produced energy surplus/shortage information 250 indicating the surplus state is transmitted to the energy management system 3 (step S5).

If the measured power generation degree 220 is equal to or greater than the setting power generation degree 330 in step S3, or if the storage battery 40 is in a non-available state in step S4, it is determined whether a reverse power flow has been detected (step S6). If a reverse power flow is detected in step S6, it is determined that the surplus or shortage of the self-produced energy in the energy receiving unit 2 is in a surplus state, and the processing proceeds to step S5. That is, in the present embodiment, when the daytime/nighttime discrimination unit 800 determines that it is daytime, the surplus/shortage information generation unit 850 determines that the self-produced energy is in a surplus state if the self-produced energy use degree 210 exceeds the setting use degree 320, the measured power generation degree 220 is less than the setting power generation degree 330, and the storage battery 40 is in an available state, and if the self-produced energy use degree 210 exceeds the setting use degree 320, the measured power generation degree 220 exceeds the setting power generation degree 330, and a reverse power flow is detected.

If no reverse power flow is detected in step S6, it is determined that the surplus or shortage of the self-produced energy in the energy receiving unit 2 is in a balanced state, and the self-produced energy surplus/shortage information 250 indicating the balanced state is transmitted to the energy management system 3 (step S7).

In the present embodiment, even when the setting use degree 320 is less than the self-produced energy use degree 210 in step S2, the measured power generation degree 220 is compared with the setting power generation degree 330 and it is determined whether the measured power generation degree 220 is equal to or greater than the setting power generation degree 330 (step S8). If the measured power generation degree 220 is equal to or greater than the setting power generation degree 330 in step S8, it is determined that the surplus or shortage of the self-produced energy in the energy receiving unit 2 is in a shortage state, and the self-produced energy surplus/shortage information 250 indicating the shortage state is transmitted to the energy management system 3 (step S9). That is, in the present embodiment, when the daytime/nighttime discrimination unit 800 determines that it is daytime, the surplus/shortage information generation unit 850 determines that the self-produced energy is in a shortage state if the self-produced energy use degree 210 is less than the setting use degree 320. If the measured power generation degree 220 is less than the setting power generation degree 330 in step S8, it is determined that the system is abnormal, and the system shifts to the state checking mode (step S10).

When it is determined in step S5 that the self-produced energy is in a surplus state, the heat storage control unit 870 sets the control of the heating and cooling device 10 to the heat storage increasing mode (step S11). As shown in FIG. 4, in the heat storage increasing mode, the heat storage control unit 870 determines whether the room temperature being cooled and heated by the air-conditioner is within the preset setting temperature range 360 (step S111). The setting temperature range 360 can be arbitrarily set, for example, and can be set to 18° C. or higher and 30° C. or lower. When it is determined in step S111 that the room temperature is within the setting temperature range 360, the heat storage control unit 870 determines whether there is a person in the room (step S112). When it is determined in step S112 that no one is present, the heat storage control unit 870 increases the heat storage action of the heating and cooling device 10 (step S113). In the present embodiment, the air-conditioner of the heating and cooling device 10 increases the cooling action when it is in the cooling state, and increases the heating action when it is in the heating state. If the air-conditioner is not in operation but is in a stopped state, it is forcibly brought into an operating state. In this way, thermal energy is stored in the air that is directly cooled by the air-conditioner and the structure, such as walls and columns, of a building that is indirectly cooled. In addition, the water heater of the heating and cooling device 10 is forcibly brought into an operating state when it is in a stopped state, and thermal energy is stored in water. In addition, when the water heater is in the operating state, the operating state is maintained. Further, in the present embodiment, in step S113, in addition to increasing the heat storage action of the heating and cooling device 10, the battery of the electric vehicle 12 is put into a charging state, the pool pump 13 is put into an operating state, and the electric vehicle 12 and the pool pump 13 are put into a power consumption state. If it is determined in step S111 that the temperature is not within the setting temperature range or if it is determined in step S112 that there is a person, it is determined whether the restriction setting of the heat storage action of the air-conditioner is enabled or disabled (step S114). When the restriction setting is enabled in step S114, the air-conditioning restriction unit 880 prohibits an increase of the heat storage action to maintain the heat storage action of the air-conditioner (step S115). That is, the current cooling state or heating state of the air-conditioner is maintained. At this time, the increase of the heat storage action of the water heater is not restricted. If the air-conditioner is not in operation but is in a stopped state, the stopped state is maintained. Further, in the present embodiment, in step S115, although the heat storage action of the air-conditioner is maintained, the battery of the electric vehicle 12 is put into a charging state, the pool pump 13 is put into an operating state, and the electric vehicle 12 and the pool pump 13 are put into a power consumption state.

Further, when it is determined in step S9 that the self-produced energy is in the shortage state, the heat storage control unit 870 sets the control of the heating and cooling device 10 to the heat storage decreasing mode (step S13). As shown in FIG. 5, in the heat storage decreasing mode, the heat storage control unit 870 determines whether the room temperature being cooled and heated by the air-conditioner is within the preset setting temperature range 360 (step S131). When it is determined in step S131 that the room temperature is within the setting temperature range 360, the heat storage control unit 870 determines whether there is a person in the room (step S132). When it is determined in step S132 that no one is present, the heat storage control unit 870 decreases the heat storage action of the heating and cooling device 10 (step S133). In the present embodiment, the air-conditioner of the heating and cooling device 10 stops the cooling action when it is in the cooling state, and stops the heating action when it is in the heating state. If the air-conditioner is not in operation but is in a stopped state, the stopped state is maintained. In addition, the water heater of the heating and cooling device 10 is put into a stopped state when it is in an operating state, and is maintained in a stopped state when it is in a stopped state. Further, in the present embodiment, in step S133, in addition to decreasing the heat storage action of the heating and cooling device 10, charging of the battery of the electric vehicle 12 is stopped, the pool pump 13 is stopped, and the electric vehicle 12 and the pool pump 13 is put into a non-power consumption state. If it is determined in step S131 that the temperature is not within the setting temperature range, or if it is determined in step S132 that there is a person, it is determined whether the restriction setting of the heat storage action of the air-conditioner is enabled or disabled (step S134). When the restriction setting is enabled in step S134, the air-conditioning restriction unit 880 prohibits the decrease of the heat storage action and maintains the heat storage action of the heating and cooling device 10 (step S135). That is, the current cooling state or heating state of the air-conditioner is maintained. At this time, the decrease of the heat storage action of the water heater is not restricted. If the air-conditioner is not in operation but is in a stopped state, the stopped state is maintained. Further, in the present embodiment, in step S135, although the heat storage action of the air-conditioner is maintained, charging of the battery of the electric vehicle 12 is stopped, the pool pump 13 is stopped, and the electric vehicle 12 and the pool pump 13 are put into a non-power consumption state.

Moreover, even when it is determined in step S7 that the self-produced energy is in a balanced state, the heat storage control unit 870 maintains the heat storage action of the heating and cooling device 10 (step S12). In addition, the battery of the electric vehicle 12 and the pool pump 13 are maintained in their operating states. Then, after steps S113, S115, S133, S135, and S12, the processing returns to step S1 to discriminate between daytime and nighttime again.

As shown in FIG. 6, when it is determined in step S1 that it is nighttime, the self-produced energy use degree 210 is compared with the setting use degree 320, and it is determined whether the self-produced energy use degree 210 is equal to or greater than the setting use degree 320 (step S14). If the setting use degree 320 is equal to or greater than the self-produced energy use degree 210 in step S14, it is determined whether the storage battery 40 is in an available state (step S15). In the nighttime, if the storage battery 40 is equal to or greater than 350, which is the setting remaining capacity at night, it is determined that the battery is in an available state. As described above, the nighttime setting remaining capacity 350 changes according to the time of day. The setting of the nighttime setting remaining capacity 350 is arbitrary, but in the present embodiment, it is set to 100% immediately after switching from day to night, 10% immediately before switching from night to day, and is set to decrease linearly during this period.

If the storage battery 40 is in an available state in step S15, it is determined that the self-produced energy in the energy receiving unit 2 is in a surplus state, and the self-produced energy surplus/shortage information 250 indicating the surplus state is transmitted to the energy management system 3 (step S16). That is, in the present embodiment, when the daytime/nighttime discrimination unit 800 determines that it is nighttime, the surplus/shortage information generation unit 850 determines that the self-produced energy is in a surplus state if the self-produced energy use degree 210 exceeds the setting use degree 320 and the storage battery 40 is in an available state.

If the storage battery 40 is in a non-available state in step S15, it is determined that the surplus or shortage of the self-produced energy in the energy receiving unit 2 is in a balanced state, and the self-produced energy surplus/shortage information 250 indicating the balanced state is transmitted to the energy management system 3 (step S17).

If the setting use degree 320 is less than the self-produced energy use degree 210 in step S14, it is determined that the surplus or shortage of the self-produced energy in the energy receiving unit 2 is in a shortage state, and the self-produced energy surplus/shortage information 250 indicating the shortage state is transmitted to the energy management system 3 (step S18). That is, in the present embodiment, when the daytime/nighttime discrimination unit 800 determines that it is nighttime, the surplus/shortage information generation unit 850 determines that the self-produced energy is in a shortage state when the self-produced energy use degree 210 is less than the setting use degree 320.

When it is determined in step S16 that the self-produced energy is in a surplus state, the heat storage control unit 870 sets the control of the heating and cooling device 10 to the heat storage increasing mode (step S19). When it is determined in step S17 that the self-produced energy is in a balanced state, the heat storage control unit 870 maintains the heat storage action of the heating and cooling device 10 (step S20). When it is determined in step S18 that the self-produced energy is in the shortage state, the heat storage control unit 870 sets the control of the heating and cooling device 10 to the heat storage decreasing mode (step S21). The control and operation of the heating and cooling device 10 in steps S19, S20, and S21, the charging control of the battery of the electric vehicle, and the operation control of the pool pump are the same as in steps S11, S12, and S13. After steps S19, S20, and S21, the processing returns to step S1 to discriminate between daytime and nighttime again.

According to the photovoltaic system 1 configured as described above, the self-produced energy surplus/shortage information 250 that takes into consideration the use state of the self-produced energy of the energy receiving unit 2 is transmitted to the energy management system 3. Therefore, the energy management system 3 can effectively use the renewable energy of the energy receiving units 2 based on the self-produced energy surplus/shortage information 250, and can quickly and simply adjust the power of each energy receiving unit 2. Further, for example, when a power adjustment plan for each energy receiving unit 2 is formulated on a monthly basis, by aggregating the self-produced energy surplus/shortage information 250 for each energy receiving unit 2 on each month, it is possible to accurately form a medium- to long-term balance of electric power in each energy receiving unit 2.

In addition, since the energy receiving unit 2 increases or decreases the heat storage action of the heating and cooling device 10 based on the self-produced energy surplus/shortage information 250, renewable energy can be effectively used within the energy receiving unit 2. In particular, when the self-produced energy is in a surplus state, the heating and cooling device 10 is forcibly operated so that the thermal energy is stored. Therefore, after the self-produced energy surplus state is eliminated, the stored thermal energy is used to decrease the power consumption of the heating and cooling device 10. As a result, surplus renewable energy can be utilized without increasing the number of storage batteries 40. In addition, when the self-produced energy is in a surplus state, the non-storage devices such as the electric vehicle 12 and the pool pump 13 are also operated, so that surplus renewable energy can also be utilized. Furthermore, the amount of electric power purchased from the commercial grid 20 can be decreased.

In addition, since the increase or decrease of the heat storage action of the air-conditioner is prohibited based on the room information of the predetermined room that is cooled or heated by the air-conditioner, the heat is stored within the range in consideration of the room conditions. At this time, since the increase or decrease of the heat storage action is not restricted for the water heater that does not affect the cooling and heating of the room, thermal energy is stored for the thermal and cooling device 10 that does not affect the cooling and heating of the room. In addition, since the operation of non-storage devices such as the electric vehicle 12 and the pool pump 13 is not restricted, it is possible to utilize surplus renewable energy within the range in consideration of the room conditions. In the present embodiment, the heat storage action is not increased or decreased when the room temperature is outside the setting temperature range 360, so that the room is not excessively cooled or heated. In addition, since the heat storage action is not increased or decreased when a person is present in the room, the air-conditioner is operated according to the setting state of the air-conditioning operation unit 2c when a person is present in the room. Furthermore, since the enabling/disabling of the restriction of the increase or decrease of the heat storage action is controlled based on the input from the air-conditioning operation unit 2c, the heat storage action can be increased or decreased when the restriction is unnecessary. For example, even if a pet enters the room and the human sensor 2b reacts to the pet, the heat storage action can be increased or decreased by disabling the restriction.

In the above-described embodiment, the heat storage action of the heating and cooling device 10 is increased, maintained, or decreased based on the self-produced energy surplus/shortage information 250, but it may be increased or maintained. Further, in the above-described embodiment, the air-conditioning restriction unit 880 prohibits the increase or decrease of the heat storage action of the air-conditioner based on the room information. However, for example, the air-conditioning restriction unit 880 may apply any restriction to the heat storage action, for example, decreasing the increase/decrease width of the heat storage action.

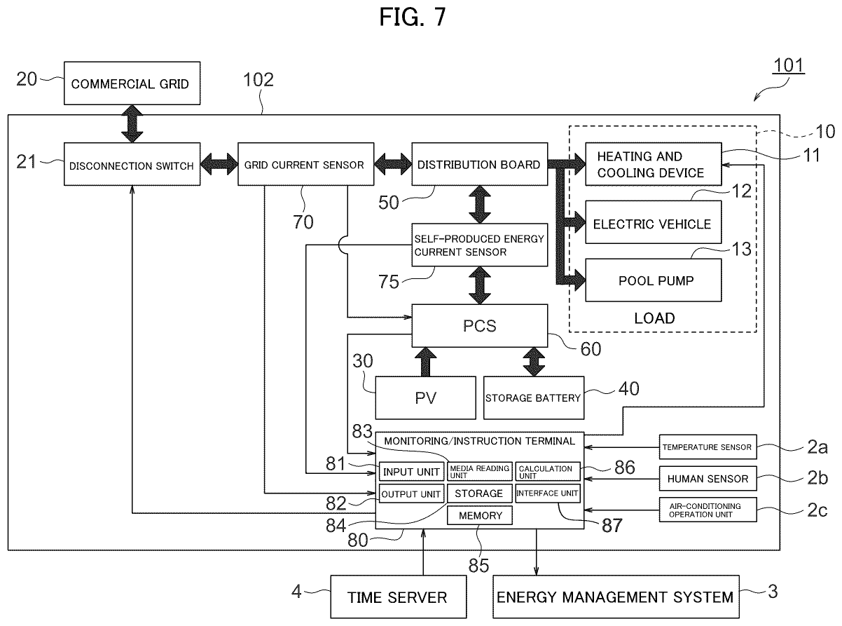

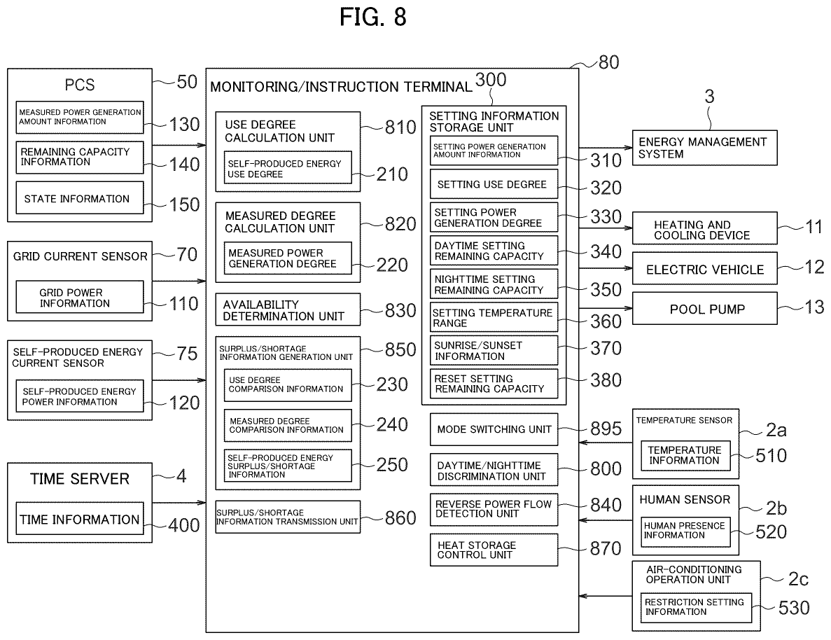

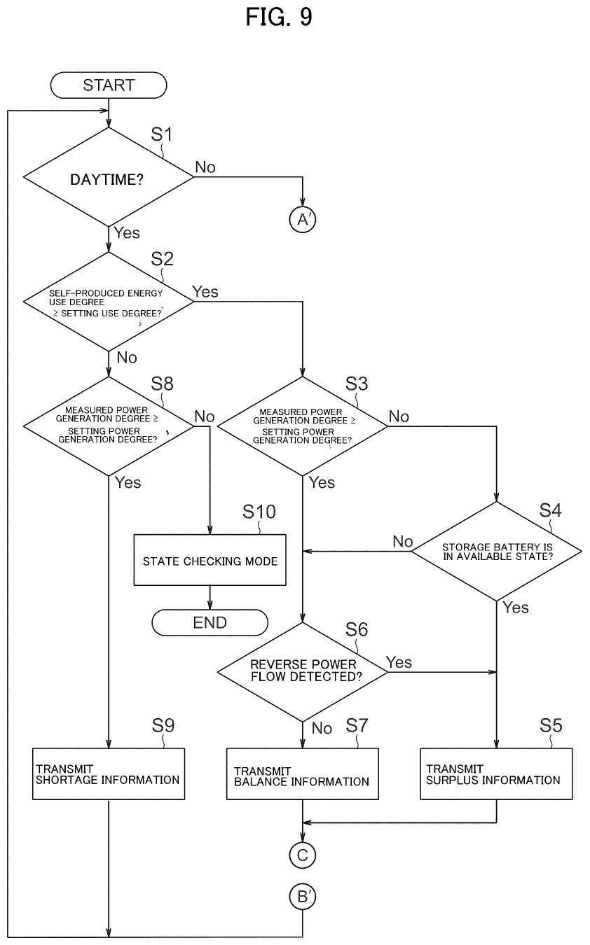

FIGS. 7 to 11 show a second embodiment of the present invention, in which FIG. 7 is a configuration block diagram of a photovoltaic system, FIG. 8 is a control block diagram of the photovoltaic system, and FIGS. 9 to 11 are flowcharts showing the operation of a photovoltaic system.

As shown in FIG. 7, in this photovoltaic system 101, an energy receiving unit 102 has a disconnection switch 21 capable of disconnecting the power supply from the commercial grid 20 to the load. FIG. 7 is the same as the above-described embodiment except for the presence of the disconnection switch 21.

As shown in FIG. 8, the monitoring/instruction terminal 80 has a mode switching unit 895 for switching the mode between a normal mode in which control is performed in a state where electric power is supplied from the commercial grid 20 to the load, and a grid disconnection mode in which control is performed in a state where the power supply from the commercial grid 20 to the load is disconnected by the disconnection switch 21. FIG. 8 is the same as the above-described embodiment except that the mode switching unit 895 is provided, a reset setting remaining capacity 380 used by the mode switching unit 895 is stored in the setting information storage unit 300, and the air-conditioning restriction unit 880 and the restriction control unit 890 are not provided.

The monitoring/instruction terminal 80 includes a daytime/nighttime discrimination unit 800, a use degree calculation unit 810, an actual measurement degree calculation unit 820, an availability determination unit 830, a reverse power flow detection unit 840, a surplus/shortage information generation unit 850, a surplus/shortage information transmission unit 860, and a heat storage control unit 870. The method of determining whether the surplus or shortage of self-produced energy in the energy receiving/supplying unit 2 is in the surplus state, the balanced state, and the shortage state is the same as in the above-described embodiment.

The mode switching unit 895 switches from the normal mode to the grid disconnection mode when a predetermined grid disconnection condition is satisfied when the self-produced energy in the normal mode is in a surplus state or a balanced state. In the present embodiment, the grid disconnection condition is whether the user has set permission for grid disconnection. The mode switching unit 895 switches from the grid disconnection mode to the normal mode when the remaining capacity of the storage battery 40 is less than the preset reset setting remaining capacity 380 in the grid disconnection mode. In the present embodiment, the heat storage control unit 870 decreases the heat storage action of the heating and cooling device 10 when the storage battery 40 in the grid disconnection mode is in the discharging state, and increases the heat storage action of the heating and cooling device 10 when the storage battery 40 in the grid disconnection mode is in the charging state or the standby state.

The operation of the photovoltaic system 101 configured as described above will be described with reference to the flowcharts of FIGS. 9 to 11.

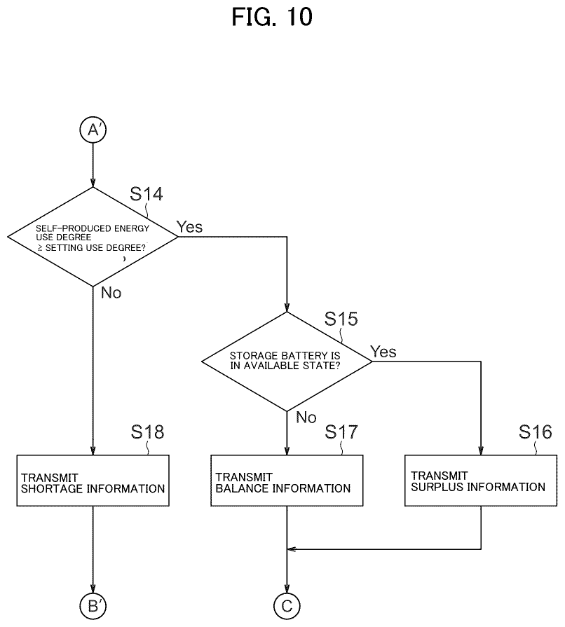

In the present embodiment, the initial state is set to the normal mode, in which electric power is supplied from the commercial grid 20. As shown in FIGS. 9 and 10, the control in the normal mode is the same as steps S1 to S9 and S14 to S18 in the above-described embodiment. In the present embodiment, if it is determined in steps S9 and S18 that it is in the shortage state, the processing immediately returns to step S1. Further, when it is determined in steps S5, S7, S16, and S17 that it is in the surplus state or the balanced state, the normal mode is shifted to the grid disconnection mode.

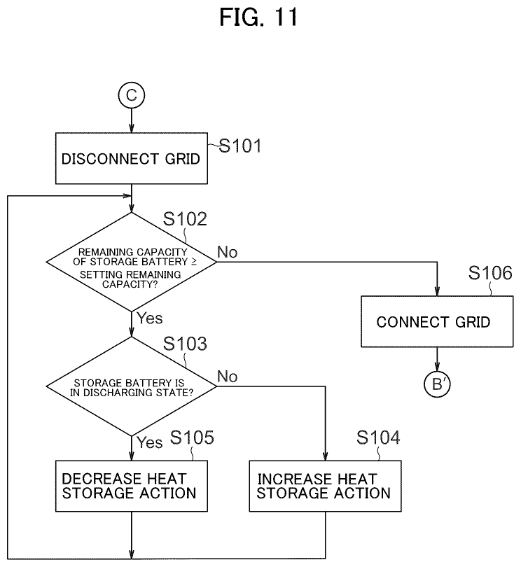

As shown in FIG. 11, when shifting to the grid disconnection mode, the disconnection switch 21 is operated to stop the power supply from the commercial grid 20 (step S101). After that, the monitoring/instruction terminal 80 determines whether the remaining capacity of the storage battery 40 is equal to or greater than the reset setting remaining capacity 380 (step S102).

In step S102, when the remaining capacity of the storage battery 40 is equal to or greater than the reset setting remaining capacity 380, it is determined whether the storage battery 40 is in a discharging state (step S103). When it is determined in step S103 that the storage battery 40 is not in a discharging state but is in a charging state or a standby state, the heat storage control unit 870 increases the heat storage action of the heating and cooling device 10 (step S104). Also, in the present embodiment, the air-conditioner increases the cooling effect when it is in the cooling state, and increases the heating effect when it is in the heating state. If the air-conditioner is not in operation but is in a stopped state, it is forcibly brought into an operating state. In addition, the water heater is forcibly brought into an operating state when it is in a stopped state, and thermal energy is stored in the water. In addition, when the water heater is in the operating state, the operating state is maintained.

When it is determined in step S103 that the storage battery 40 is in a discharging state, the heat storage control unit 870 decreases the heat storage action of the heating and cooling device 10 (step S105). Also, in the present embodiment, the air-conditioner of the heating and cooling device 10 stops the cooling action when it is in the cooling state, and stops the heating action when it is in the heating state. If the air-conditioner is not in operation but is in a stopped state, the stopped state is maintained. The water heater is put into a stopped state when it is in an operating state, and the stopped state is maintained when it is in a stopped state. Then, after steps S104 and S105, the processing returns to step S102, and the remaining capacity of the storage battery 40 and the reset setting remaining capacity 380 are compared again. This operation is repeated until the remaining capacity of the storage battery 40 falls below the reset setting remaining capacity 380.

In step S102, when the remaining capacity of the storage battery 40 is less than the reset setting remaining capacity 380, the mode is shifted to the normal mode, the disconnection switch 21 is reconnected, and the power supply from the commercial grid 20 is resumed (step S106). The reset setting remaining capacity 380 can be set arbitrarily, and is set to 30% in the present embodiment. As shown in FIG. 11, after shifting to the normal mode, the processing returns to step S1.

According to the photovoltaic system 101 configured as described above, the self-produced energy surplus/shortage information 250 that takes into account the use state of renewable energy in the energy receiving/supplying unit 2 is transmitted to the energy management system 3. Therefore, the energy management system 3 can effectively utilize renewable energy in the energy receiving/supplying units 2 based on the self-produced energy surplus/shortage information 250, and can quickly and simply adjust the power of each energy receiving/supplying unit 2. Moreover, since the commercial grid 20 is disconnected when the self-produced energy is in a surplus state or a balanced state, the amount of electric power purchased from the commercial grid 20 can be decreased.

Further, in the energy receiving unit 2, when the grid is disconnected, the heat storage action of the heating and cooling device 10 is increased or decreased based on the remaining capacity information 140 and the state information 150 of the storage battery 40, so that the renewable energy can be effectively used within the energy receiving unit 2. That is, when the storage battery 40 satisfies a predetermined condition at the time of grid disconnection, the heating and cooling device 10 is forcibly operated to store thermal energy. Thus, the renewable energy can be utilized without increasing the number of storage batteries 40. In the present embodiment, the increase or decrease of the heat storage action of the air-conditioner is not restricted, but the increase or decrease of the heat storage action may be restricted as in the above-described embodiment.

In each of the above-described embodiments, the power information 110, 120 is acquired from the current sensors 70 and 75, but the power information may be acquired from the power meter or the power conditioner 60, for example. Any method can be used to acquire the power information 110 and 120. In addition, the method of acquiring other information can be changed arbitrarily.

Moreover, in each of the above-described embodiments, the heat storage control unit 870 is arranged in the monitoring/instruction terminal 80, but the heat storage control unit 870 may be arranged in the heating and cooling device 10. In addition, although an air-conditioner and a water heater are exemplified as the heating and cooling device 10, for example, it may be a cooling and heating device that heats and/or cools a liquid or solid heat storage material embedded in the floor or wall. When an air-conditioner and another cooling and heating device cool and heat the same room, the other cooling and heating device may be linked with the air-conditioner to increase or restrict the heat storage action.

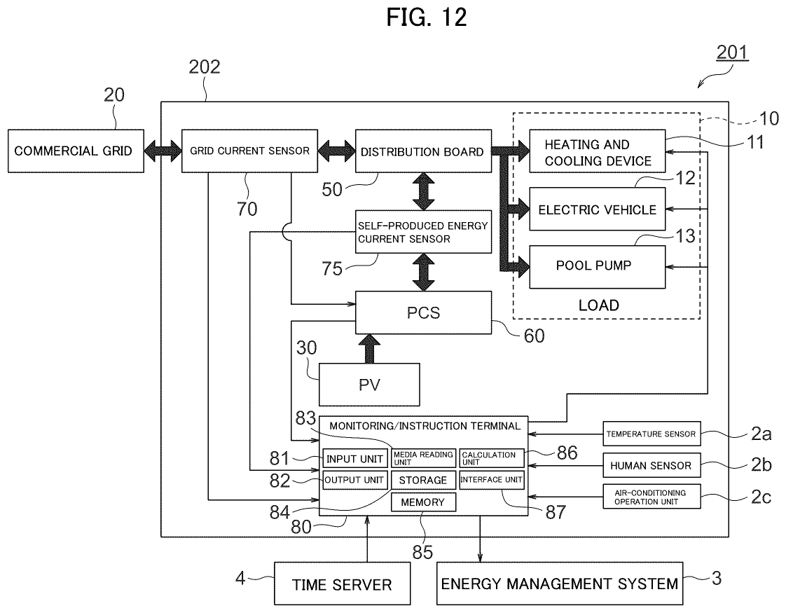

In each of the above-described embodiments, when it is determined that it is daytime, steps S2, S3, S4, and S6 are performed to determine that the self-produced energy is in a surplus state. However, for example, in a system or the like that does not cause a reverse power flow, step S6 related to the reverse power flow may be omitted. Further, for example, as shown in FIG. 12, in a system or the like that does not have the storage battery 40, the self-produced energy power information may be information related to the electric power supplied only from the photovoltaic device, and step S4 related to the storage battery 40 may be omitted. Furthermore, the order of steps S2, S3, S4, and S6 can be changed as appropriate.

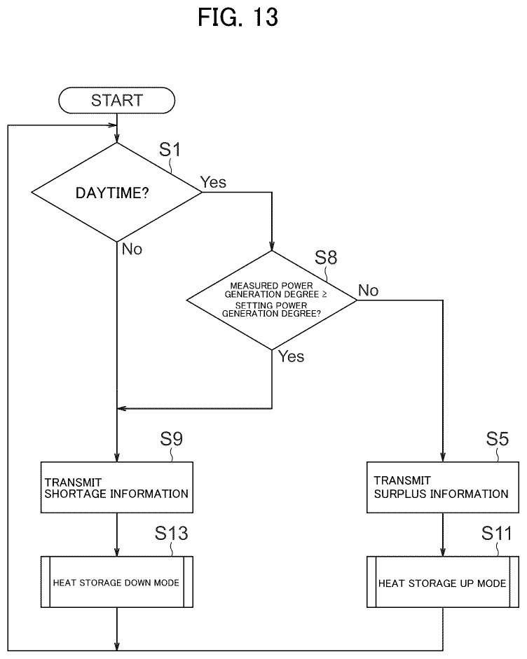

Furthermore, for example, as shown in FIG. 13, it is also possible to generate the self-produced energy surplus/shortage information 250 based only on the measured degree comparison information 240. In the modified example of FIG. 13, steps S2, S3, S4, S6, S7 and S12 of the first embodiment are omitted, and when it is determined in step S1 that it is daytime, the measured power generation degree 220 and the setting power generation degree 330 are compared, and it is determined whether the measured power generation degree 220 is equal to or greater than the setting power generation degree 330 (step S8). Then, in step S8, when the measured power generation degree 220 is equal to or higher than the setting power generation degree 330, it is determined that the surplus or shortage of the self-produced energy in the energy receiving unit 2 is in a surplus state and the self-produced energy surplus/shortage information 250 indicating the shortage state is transmitted to the energy management system 3 (step S9). Further, when the measured power generation degree 220 is less than the setting power generation degree 330 in step S3, it is determined that the surplus or shortage of the self-produced energy in the energy receiving unit 2 is in a surplus state, and the self-produced energy surplus/shortage information 250 indicating the surplus state is transmitted to the energy management system 3 (step S5). In the modified example of FIG. 13, in the daytime, the self-produced energy is classified into two states, a surplus state and a shortage state. In the modified example of FIG. 13, the operation in the nighttime is the same as in the first embodiment, and the self-produced energy is classified into three states, surplus state, balanced state, and shortage state.

Further, in each of the above-described embodiments and the modified example of FIG. 13, when generating the self-produced energy surplus/shortage information 250, the measured power generation degree 220 is obtained by dividing the measured power generation amount by the setting power generation amount, and then the measured power generation degree 220 is compared with the setting power generation degree 330. However, other methods may be used as long as the self-produced energy surplus/shortage information 250 is generated based on the measured power generation amount and the setting power generation amount. For example, the measured power generation amount and the setting power generation amount may be easily compared, it may be determined that the self-produced energy in the energy receiving unit 2 is in a surplus state if the measured power generation amount exceeds the setting power generation amount, and it may be determined that the self-produced energy in the energy receiving unit 2 is in a shortage state if the measured power generation amount is lower than the setting power generation amount. That is, the surplus/shortage information generation unit may generate the self-produced energy surplus/shortage information based on at least the measured power generation amount of the photovoltaic device and the preset setting power generation amount. In addition, the setting power generation amount of the setting power generation amount information 310 may be changed based on the information related to power selling or power purchase in the energy receiving unit 2. For example, if the user permits the energy receiving unit 2 to sell power, or if a mode that prioritizes power selling is set, the setting power generation amount may be decreased so that it becomes easy to determine that the self-produced energy in the energy receiving unit 2 is in the surplus state. In this case, how much the setting power generation amount will be decreased is arbitrary, but for example, it can be set to 80% of the normal setting power generation amount. On the other hand, for example, if the user permits the energy receiving unit 2 to purchase power, or if the mode that prioritizes power purchasing is set, the setting power generation amount may be increased so that it becomes easy to determine that the self-produced energy in the energy receiving unit 2 is in the shortage state. In this case, how much the setting power generation amount will be increased is arbitrary, but for example, it can be set to 120% of the normal setting power generation amount.

In each of the above-described embodiments, when it is determined that it is nighttime, the self-produced energy surplus/shortage information 250 is generated based on both the use degree comparison information 230 and whether the storage battery 40 is in an available state. However, for example, the self-produced energy surplus/shortage information 250 may be generated based on either one. In addition, the surplus/shortage information generation unit 850 classifies the self-produced energy into three states of surplus state, balanced state, and shortage state. However, the surplus state may be more finely classified into four or more stage, or may be classified into two states, such as whether it is in a surplus state or whether it is in a shortage state. The number of classifications and types can be changed as appropriate according to the device, the program or the like used by the self-produced energy surplus/shortage information 250. For example, it is possible to divide a surplus state into multiple ranks, or divide a shortage state into multiple ranks.

Further, in each of the above-described embodiments, when the heat storage control unit 870 decreases the heat storage action of the heating and cooling device 10, the operation of the heating and cooling device 10 is stopped. However, the cooling action or the heating action of the heating and cooling device 10 may be decreased.

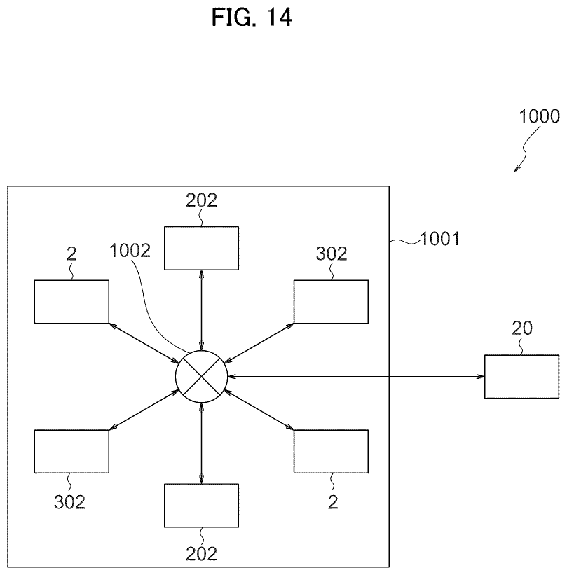

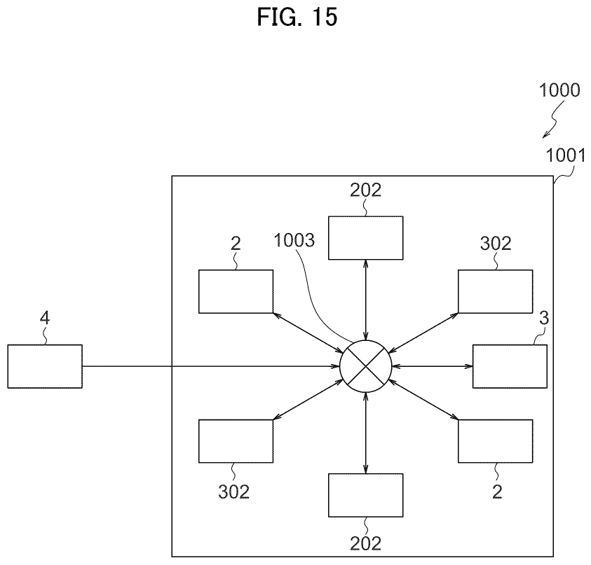

FIGS. 14 and 15 show the third embodiment of the present invention, in which FIG. 14 is a block diagram related to energy of a single-microgrid energy supply and demand system, and FIG. 15 is a block diagram related to communication of a single-microgrid energy supply and demand system.

In this energy supply and demand system 1000, in a microgrid 1001, energy is supplied from the energy receiving units 2, 202, and 302 in which the self-produced energy is in a surplus state to the energy receiving units 2, 202, and 302 in which the self-produced energy is in a shortage state. As shown in FIG. 14, a plurality of energy receiving units 2, 202, and 302 belong to the microgrid 1001, and the energy receiving units 2, 202, and 302 are electrically connected by a power grid 1002. In the present embodiment, the power grid 1002 is connected to the commercial grid 20 of a power company. In the present embodiment, the microgrid 1001 includes the energy receiving unit 2 similar to that in FIG. 1 having the photovoltaic device 30 and the storage battery 40, the energy receiving unit 202 similar to that of FIG. 12 having the photovoltaic device 30 but without the storage battery 40, and the energy receiving unit 302 without the photovoltaic device 30 and the storage battery 40.

As shown in FIG. 15, the energy receiving units 2, 202, and 302 are communicably connected by a communication network 1003. In the present embodiment, there is an administrator who manages the energy supply and demand state of the microgrid 1001, and the energy management system 3 operated by the administrator is connected to the communication network 1003. The energy management system 3 is configured of a computer such as a personal computer or a workstation, and includes an input unit, an output unit, a media reading unit, a storage, a memory, a calculation unit, an interface unit, similarly to the monitoring/instruction terminal 80 of each embodiment, which are interconnected by a system bus. The energy receiving units 2, 202, and 302 transmits the self-produced energy surplus/shortage information 250 related to the surplus/shortage of self-produced energy to the energy management system 3. In the energy receiving unit 2 that has the photovoltaic device 30 and the storage battery 40, in the procedures of the flowcharts of FIGS. 3 to 6, the self-produced energy surplus/shortage information 250 in which the self-produced energy is classified into either one of the surplus state, the balanced state, or the shortage state is generated. In addition, in the energy receiving unit 202 that has the photovoltaic device 30 and does not have the storage battery 40, in the procedure of the flowchart of FIG. 13, the self-produced energy surplus/shortage information 250 in which the self-produced energy is classified into either one of the surplus state or the shortage state is generated. Furthermore, in the energy receiving unit 302 that does not include the photovoltaic device 30 and the storage battery 40, since the self-produced energy is always in a shortage state, the self-produced energy surplus/shortage information 250 is always in the shortage state without passing through a predetermined procedure.

The energy management system 3 forms a supply and demand adjustment unit that supplies electric power from the energy receiving units 2, 202, and 302 in which the self-produced energy is classified into a surplus state to the energy receiving units 2, 202, and 302 in which the self-produced energy is classified into a shortage state via the power grid 1002 based on the transmitted self-produced energy surplus/shortage information 250. Specifically, the energy management system 3 receives electric power from the energy receiving units 2, 202, and 302 in a surplus state to the power grid 1002, and transmits electric power from the power grid 1002 to the energy receiving units 2, 202, and 302 in a shortage state. In the matching of the energy receiving units 2, 202, and 302 in the surplus state and in the shortage state, if there is an energy receiving unit 2, 202, or 302 in the shortage state, from the viewpoint of preventing conflict of information, it is preferable to find the other energy receiving unit 2, 202, or 302 in the surplus state and perform the matching. In this case, the consumer of each energy receiving unit 2 conducts energy trading transactions with the other consumer via the administrator of the energy management system 3. By repeating this energy trading and updating the surplus state/shortage state of the energy receiving units 2, 202, and 302, the overall energy balance in the microgrid 1001 is achieved. According to this energy supply and demand system 1000, under the control of the energy management system 3, renewable energy in the microgrid 1001 can be effectively used, and the power of each energy receiving unit 2 can be adjusted accurately.

Regarding the energy receiving units 2, 202, and 302 in the surplus state in the third embodiment, it is preferable to rank the surplus state so that electric power is preferentially transmitted from the energy receiving units 2, 202, and 302 having the highest rank. The ranking of the surplus state is basically based on the surplus amount of energy, but it is preferable that the demands of each consumer are also taken into account. For example, when a consumer desires to restrict the selling of power, it is possible to receive the restriction setting and lower the rank according to the desired degree of restriction.

Further, in the third embodiment, energy trading is performed via the administrator of the energy management system 3, but the transaction of energy trading may be performed directly between the consumers of the energy receiving units 2, 202, and 302. In this case, the energy management system 3 becomes unnecessary because the self-produced energy surplus/shortage information 250 is shared among the energy receiving units 2, 202, and 302. In energy trading between consumers, it is preferable to construct a system in which a consumer in a shortage state selects a consumer in a surplus state and applies for a transaction from the viewpoint of preventing conflict of information. In addition, when sharing the self-produced energy surplus/shortage information 250, it is preferable to secure transaction security using block chain technology.

In addition, the energy receiving unit 102 of the second embodiment may belong to the microgrid 1001 of the third embodiment. In this case, the energy management system 3 may remove the energy receiving unit 102 from the management targets while the disconnection switch 21 of the energy receiving unit 102 is disconnected. Further, in the third embodiment, the surplus/shortage information generation device is arranged in each of the energy receiving units 2, 202, and 302. However, the information necessary for generating the self-produced energy surplus/shortage information may be transmitted from the energy receiving units 2, 202, and 302 to the energy management system 3, and the energy management system 3 may classify the surplus state/shortage state of the self-produced energy of each of the energy receiving units 2, 202, and 302. In this case, the energy management system 3 serves as a surplus/shortage information generation device.

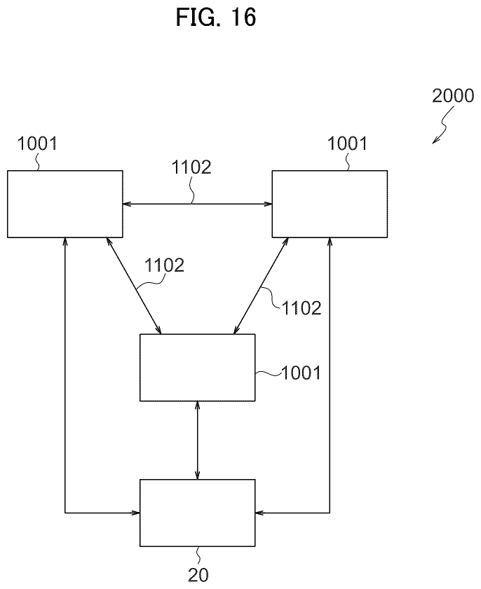

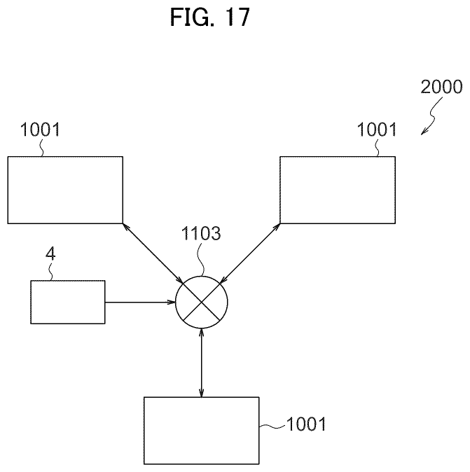

FIGS. 16 and 17 show a fourth embodiment of the present invention, in which FIG. 16 is a block diagram related to energy in a multiple-microgrid energy supply and demand system, and FIG. 17 is a diagram related to communication in a multiple-microgrid energy supply and demand system.

As shown in FIG. 16, in this energy supply and demand system 200, the microgrids 1001 of the third embodiment are electrically connected to each other by power lines 1102. In addition, as shown in FIG. 17, the energy management systems 3 of each microgrid 1001 are connected for communication via a communication network 1103, respectively. Each energy management system 3 acquires the self-produced energy surplus/shortage information 250 of the energy receiving units 2, 202, and 302 belonging to the other microgrids 1001 from the energy management systems 3 that manage the other microgrids 1001 and shares the self-produced energy surplus/shortage information 250. Based on the shared self-produced energy surplus/shortage information 250, each energy management system 3 supplies electric power from the energy receiving unit 2 in which the self-produced energy is classified into the surplus state to the energy receiving unit 2 in which the self-produced energy is classified into the shortage state via the power grid 1002 and the power line 1102. At this time, when the microgrid 1001 to which the energy receiving unit 2 in the surplus state belongs and the microgrid 1001 to which the energy receiving unit 2 in the shortage state belongs are different, each energy management system 3 receives electric power from the energy receiving units 2, 202, and 302 in the surplus state to the power grid 1002, transmits electric power from the microgrid 1001 to which the energy receiving units 2, 202, and 302 in the surplus state belong to the microgrid 1001 to which the energy receiving units 2, 202, and 302 in the shortage state belong via the power lines 1102, and transmits electric power from the power grid 1002 to the energy receiving units 2, 202, and 302 in the shortage state. In the matching of the energy receiving units 2, 202, and 302 in the surplus state and in the shortage state, if there is an energy receiving unit 2, 202, or 302 in the shortage state, from the viewpoint of preventing conflict of information, it is preferable to find the other energy receiving unit 2, 202, or 302 in the surplus state and perform the matching. In this case, the consumer of each energy receiving unit 2 conducts energy trading transactions with the other consumer via the administrator of the energy management system 3. According to this energy supply and demand system 1000, under the control of the energy management system 3, renewable energy in the microgrid 1001 can be effectively used, and the power of each energy receiving unit 2 can be adjusted accurately.

Regarding the energy receiving units 2, 202, and 302 in the surplus state in the fourth embodiment, it is preferable to rank the surplus state so that electric power is preferentially transmitted from the energy receiving units 2, 202, and 302 having the highest rank. The ranking of the surplus state is basically based on the surplus amount of energy, but it is preferable that the demands of each consumer are also taken into account. For example, when a consumer desires to restrict the selling of power, it is possible to receive the restriction setting and lower the rank according to the desired degree of restriction.

Also, in the fourth embodiment, energy trading is performed via the administrator of the energy management system 3, but the transaction of energy trading may be performed directly between the consumers of the energy receiving units 2, 202, and 302. In this case, the energy management system 3 becomes unnecessary because the self-produced energy surplus/shortage information 250 of the microgrid 1001 to which the energy receiving units 2, 202, and 302 belong and the self-produced energy surplus/shortage information 250 of the other microgrids 1001 are shared among the energy receiving units 2, 202, and 302. When sharing the self-produced energy surplus/shortage information 250, it is preferable to secure transaction security using block chain technology.

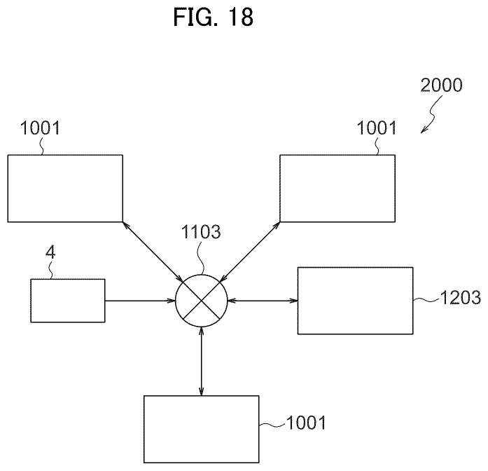

In addition, in the fourth embodiment, electric power is transmitted and received for each of the energy receiving units 2, 202, and 302, but it is also possible to transmit and receive electric power for each microgrid 1001. For example, based on the energy surplus/shortage state of each of the energy receiving units 2, 202, and 302 for each microgrid 1001, the energy surplus/shortage state may be determined for each microgrid 1001, and electric power may be transmitted from the microgrid 1001 in the energy shortage state to the microgrid 1001 in the energy surplus state. Regarding the energy surplus/shortage of each microgrid 1001, for example, the self-produced energy surplus/shortage information 250 of the energy receiving units 2, 202, and 302 may be aggregated by taking the weight according to the scale or the like of the energy receiving units 2, 202, and 302 into consideration. In this way, it is possible to determine whether the energy of the microgrid 1001 as a whole is in a surplus state or a shortage state. At this time, for example, as shown in FIG. 18, an overall management system 1203 for comprehensively managing the microgrids 1001 may be provided by connecting to the communication network 1103, and each energy management system 3 may transmit information related to the surplus/shortage state of the energy of each microgrid 1001 to the overall management system 1203. In this case, the overall management system 1203 supplies electric power from the microgrid 1001 in the surplus state to the microgrid 1001 in the shortage state through the power lines 1102. In the matching of the microgrids 1001 in the surplus state and in the shortage state, if there is a microgrid 1001 in the shortage state, from the viewpoint of preventing conflict of information, it is preferable to find the other microgrid 1001 in the surplus state and perform the matching. Regarding the microgrids 1001 in the surplus state, it is preferable to rank the surplus state so that electric power is preferentially transmitted from the microgrid 1001 having the highest rank. The ranking of the surplus state is basically based on the surplus amount of energy, but it is preferable that the demands of each administrator are also taken into account. For example, when an administrator desires to restrict the selling of power, it is possible to receive the restriction setting and lower the rank according to the desired degree of restriction. In this case, the administrator of each microgrid 1001 conducts energy trading through the administrator of the overall management system 1203. In addition, the overall management system 1203 may become unnecessary when information related to the energy surplus/shortage state of each microgrid 1001 is shared by the energy management systems 3 of each microgrid 1001. In this way, the administrators of each microgrid 1001 can directly conduct energy trading transactions. In energy trading between administrators, it is preferable to construct a system in which an administrator in a shortage state selects an administrator in a surplus state and applies for a transaction from the viewpoint of preventing conflict of information. In addition, when sharing the information related to the energy surplus/shortage state of each microgrid 1001, it is preferable to secure transaction safety using blockchain technology.

Further, in the third and fourth embodiments, an example has been shown in which the energy receiving units 2 and 202 equipped with a photovoltaic device belongs to the microgrid 1001, but an energy receiving unit equipped with another renewable energy power generation device such as a wind power generation device may belong to the microgrid 1001. That is, it is sufficient as long as energy is supplied from the energy receiving unit in the surplus state to the energy receiving unit in the shortage state based on the self-produced energy surplus/shortage information of each energy receiving unit. As a result, it is possible to solve the conventional problem that electric power cannot be finely adjusted for each energy receiving unit in a microgrid.

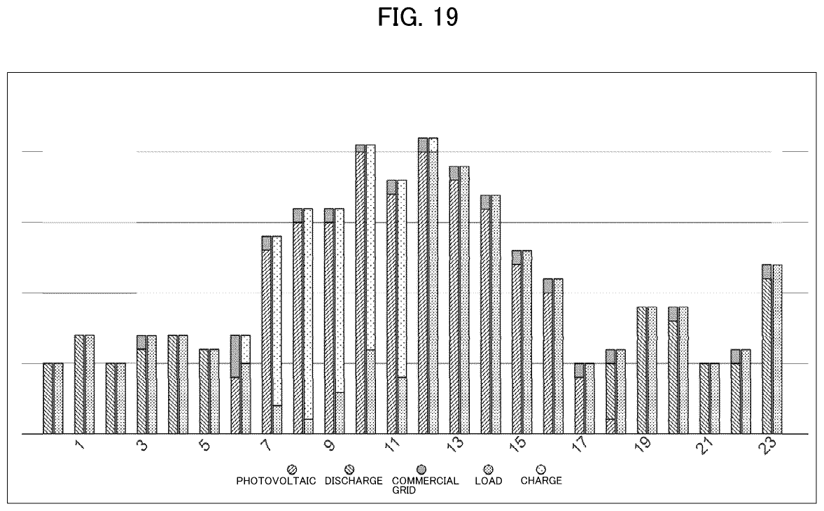

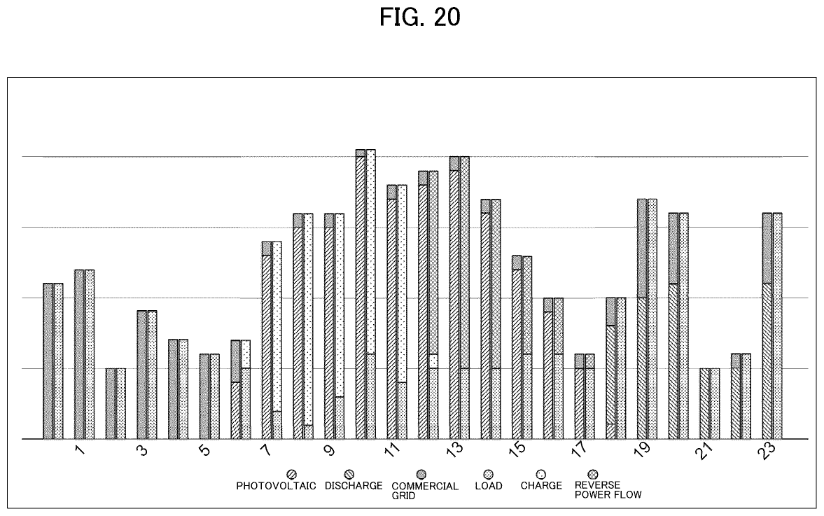

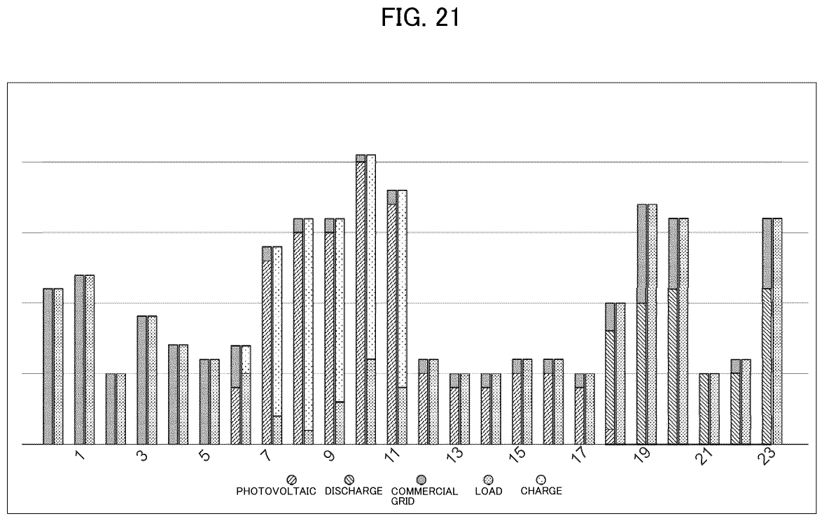

FIG. 19 shows data obtained by applying the photovoltaic system of the first embodiment to a real house. Almost the same data as in FIG. 19 was obtained not only for a system in which a reverse power flow is allowed as in the first embodiment, but also for a system in which a reverse power flow is not allowed. FIGS. 19 to 21 are graphs showing hourly power supply amounts by a commercial grid, a photovoltaic system, and a storage battery, and hourly power consumption amounts by a load, a storage battery, and a reverse power flow, in which FIG. 19 shows an example, FIG. 20 shows a first comparative example, and FIG. 21 shows a second comparative example. The first and second comparative examples are data obtained in a house to which a conventional photovoltaic system that does not use the self-produced energy use degree and self-produced energy surplus/shortage information is applied, the first comparative example is an example in which a system that allows a reverse power flow is applied, and the second comparative example is an example in which a system that does not allow a reverse power flow is applied.

As shown in FIG. 20, in the first comparative example, a reverse power flow occurs between 12:00 and 17:00. In addition, as shown in FIG. 21, in the second comparative example, the electric power supplied from the photovoltaic system between 12:00 and 16:00 is significantly less than that between 7:00 and 11:00. These are caused by supplying renewable energy obtained from the photovoltaic system to the commercial grid side or suppressing and discarding it because the electric power cannot be consumed by loads, storage batteries, and the like.

On the other hand, in the Example, as shown in FIG. 19, the power consumption is intentionally increased by forcibly operating the air-conditioner, which is a heating and cooling device, between 12:00 and 16:00, so that not reverse power flow occurred. In addition, even in the Example in which a system in which a reverse power flow is not allowed is applied, the amount of suppression of renewable energy obtained by the photovoltaic system was less than in the second comparative example. At this time, the room was cooled by the air-conditioner to the extent that it would not become excessive, and thermal energy was stored. Then, the power consumption by the air-conditioner after 18:00 after sunset can be decreased, the amount of discharge of the storage battery can be decreased, and the amount of power supplied from the commercial grid can be decreased until dawn, thereby decreasing the amount of power purchased. As shown in FIG. 19, the amount of power supplied from the commercial grid decreases particularly from 0:00 to 5:00, and the utilization efficiency of renewable energy is improved.

Although the embodiment of the invention has been described above, the invention according to claims is not to be limited to the above-mentioned embodiment. Further, it should be noted that all combinations of the features described in the embodiment are not essential to the means for solving the problems of the invention.

### REFERENCE SIGNS LIST

1 Photovoltaic system
2 Energy receiving unit
3 Energy management system
10 Heating and cooling device
20 Commercial grid
30 Photovoltaic device
40 Storage battery
70 Grid current sensor
75 Renewable energy current sensor
80 Monitoring/instruction terminal
101 Photovoltaic system
102 Energy receiving unit
110 Grid power information
120 Self-produced energy power information
140 Remaining capacity information
150 State information
201 Photovoltaic system
202 Energy receiving unit
210 Self-produced energy use degree
220 Measured power generation degree
230 Use degree comparison information
240 Measured degree comparison information
250 Self-produced energy surplus/shortage information
302 Energy receiving unit
310 Setting power generation amount information
320 Setting use degree
330 Setting power generation degree
340 Daytime setting remaining capacity
350 Nighttime setting remaining capacity
510 Temperature information
520 Human presence information
800 Daytime/nighttime discrimination unit
810 Use degree calculation unit
820 Measured degree calculation unit
830 Availability determination unit
840 Reverse power flow detection unit
850 Surplus/shortage information generation unit
870 Heat storage control unit
880 Air-conditioning restriction unit
890 Restriction control unit
1000 Energy supply and demand system
1001 Microgrid
1002 Power grid

1. A self-produced energy surplus/shortage information generation device that generates information related to surplus or shortage of self-produced energy in an energy receiving unit in which electric power supplied from a commercial grid and a photovoltaic device is consumed by a load, the device comprising:
a daytime/nighttime discrimination unit that discriminates between daytime and nighttime; and
a surplus/shortage information generation unit that generates self-produced energy surplus/shortage information related to surplus or shortage of self-produced energy in the energy receiving unit based on a measured power generation amount of the photovoltaic device and a preset setting power generation amount when the daytime/nighttime discrimination unit determines that it is daytime.

2. The surplus/shortage information generation device according to claim 1, wherein
the self-produced energy surplus/shortage information is classified depending on at least whether the self-produced energy in the energy receiving unit is in a surplus state and whether the self-produced energy in the energy receiving unit is in a shortage state.

3. (canceled)

4. (canceled)

5. The self-produced energy surplus/shortage information generation device according to claim 1, further comprising:
a measured degree calculation unit that calculates a degree of the measured power generation amount with respect to the setting power generation amount based on the measured power generation amount and the setting power generation amount as a measured power generation degree, wherein
the surplus/shortage information generation unit generates the self-produced energy surplus/shortage information based on measured degree comparison information obtained by comparing the measured power generation degree with a preset setting power generation degree when the daytime/nighttime discrimination unit determines that it is daytime.

6. The self-produced energy surplus/shortage information generation device according to claim 1, further comprising:
a use degree calculation unit that calculates a use degree of electric power supplied from the photovoltaic device in entire supply power based on grid power information related to electric power supplied from the commercial grid and self-produced energy power information related to electric power supplied from the photovoltaic device as a self-produced energy use degree, wherein
the surplus/shortage information generation unit generates the self-produced energy surplus/shortage information based on the measured power generation amount, the setting power generation amount, and use degree comparison information obtained by comparing the self-produced energy use degree and a preset setting use degree.

7. The self-produced energy surplus/shortage information generation according to claim 6, wherein
electric power is supplied to the load from a storage battery in addition to the commercial grid and the photovoltaic device,
the self-produced energy power information relates to electric power supplied from the photovoltaic device and the storage battery, and
the use degree calculation unit calculates a use degree of the electric power supplied from the photovoltaic device and the storage battery in the entire supplied electric power as the self-produced energy use degree.

8. The self-produced energy surplus/shortage information generation device according to claim 7, further comprising:
an availability determination unit that determines whether the storage battery is in an available state or a non-available state, wherein
the surplus/shortage information generation unit generates the self-produced energy surplus/shortage information based on the measured power generation amount and the setting power generation amount, the use degree comparison information, and whether the storage battery is in the available state or the non-available state when the daytime/nighttime discrimination unit determines that it is daytime.

9. The self-produced energy surplus/shortage information generation device according to claim 8, wherein
the availability determination unit determines whether the storage battery is in the available state or the non-available state based on the time of day and a remaining capacity of the storage battery when the daytime/nighttime discrimination unit determines that it is night, and
the surplus/shortage information generation unit generates the self-produced energy surplus/shortage information based on the use degree comparison information and whether the storage battery is in the available state or the non-available state when the daytime/nighttime discrimination unit determines that it is nighttime.

10. The self-produced energy surplus/shortage information generating apparatus according to claim 9, further comprising:
a reverse power flow detection unit that detects a reverse power flow in which electric power is supplied from the photovoltaic device to the commercial grid, wherein
the surplus/shortage information generation unit generates the self-produced energy surplus/shortage information based on the measured power generation amount, the setting power generation amount, the use degree comparison information, whether the storage battery is in the available state or the non-available state, and whether the reverse power flow is detected by the reverse power flow detection unit when the daytime/nighttime discrimination unit determines that it is daytime.

11. (canceled)

12. (canceled)

13. A self-produced energy surplus/shortage information generation method for generating information related to surplus or shortage of self-produced energy in an energy receiving unit in which electric power supplied from a commercial grid and a photovoltaic device is consumed by a load, the method comprising:
discriminating between daytime and nighttime;
generating self-produced energy surplus/shortage information related to surplus or shortage of self-produced energy in the energy receiving unit based on a measured power generation amount of the photovoltaic device and a preset setting power generation amount when it is determined that it is daytime.

14. (canceled)

15. (canceled)
